(19) United States
(12) Patent Application Publication
(10) Pub. No.: US 2026/0371808 A1
(43) Pub. Date: Nov. 19, 2026

(54) MIXED PACKAGING ARRANGEMENTS IN LIGHT-EMITTING DIODE DEVICES

(71) Applicant: CreeLED, Inc., Durham, NC (US)

(72) Inventors: Colin Blakely, Raleigh, NC (US); David Suich, Durham, NC (US); Scott Wegner, Boulder, CO (US); Robert Wilcox, Rolesville, NC (US)

(21) Appl. No.: 19/206,332

(22) Filed: May 13, 2025

(51) Int. Cl. H10H 29/24; H10H 29/14; H10H 29/85; H10H 29/855

(52) U.S. Cl. CPC H10H 29/24; H10H 29/142; H10H 29/855; H10H 29/857

(57) ABSTRACT

Light-emitting diode (LED) devices and more particularly mixed packaging arrangements in LED devices are disclosed. LED structures include different types of LED emitters, including LED packages and bare LED chips, assembled in a common LED device. Bare LED chips are mounted to underlying submounts, such as printed circuit boards, without intervening package elements, such as package submounts and/or lead frame structures. Exemplary LED devices include mixed arrangements of LED emitters configured to selectively provide various emission characteristics such as beam angles and/or wavelengths of light. Exemplary applications include horticulture lighting devices where beam angles and/or peak wavelength may be selectively adjusted by independently controlling various LED emitters of the mixed arrangements.

### FIELD OF THE DISCLOSURE

The present disclosure relates to light-emitting diode (LED) devices, and more particularly to mixed packaging arrangements in LED devices.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new applications, including LED displays, lighting devices for general illumination, and horticulture applications, among others.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from gallium nitride, gallium phosphide, aluminum nitride, indium nitride, gallium-indium-based materials, gallium arsenide-based materials, and/or from organic semiconductor materials.

LED technology is increasingly being developed for horticulture applications where emissions are provided to stimulate photosynthesis in growing plants. LED manufacturers for horticulture applications must balance multiple application tradeoffs of efficacy, longevity, spectral optimization, and optical distribution.

The art continues to seek improved LEDs and solid-state lighting devices having desirable illumination characteristics capable of overcoming challenges associated with conventional lighting devices.

### SUMMARY

The present disclosure relates to light-emitting diode (LED) devices, and more particularly to mixed packaging arrangements in LED devices. LED structures include different types of LED emitters, including LED packages and bare LED chips, assembled in a common LED device. Bare LED chips are mounted to underlying submounts, such as printed circuit boards, without intervening package elements, such as package submounts and/or lead frame structures. Exemplary LED devices include mixed arrangements of LED emitters configured to selectively provide various emission characteristics such as beam angles and/or wavelengths of light. Exemplary applications include horticulture lighting devices where beam angles and/or peak wavelength may be selectively adjusted by independently controlling various LED emitters of the mixed arrangements.

In one aspect, an LED device comprises: a submount comprising a printed circuit board; a first LED emitter on the submount, the first LED emitter configured to provide light having a first peak wavelength and a first beam angle; and a second LED emitter on the submount, the second LED emitter configured to provide light having the first peak wavelength and a second beam angle, the first beam angle being narrower than the second beam angle. The LED device may further comprise: an LED driver on the submount, the LED driver configured to electrically activate the first LED emitter and the second LED emitter independently of one another to change between the first beam angle and the second beam angle. In certain embodiments, the first beam angle differs from the second beam angle by at least ten degrees. In certain embodiments, the first beam angle differs from the second beam angle in a range from ten degrees to thirty degrees. In certain embodiments, the first beam angle is up to 120 degrees and the second beam angle is up to 140 degrees. In certain embodiments, the first peak wavelength is in a range from 630 nanometers (nm) to 780 nm. In certain embodiments: the first LED emitter comprises an LED package with a first LED chip mounted to a package submount and a lens over the first LED chip; and the second LED emitter comprises a second LED chip mounted directly to the submount. The LED device may further comprise a lumiphoric material on the second LED emitter and on a portion of the submount adjacent the second LED emitter. In certain embodiments, the first LED emitter is one of a plurality of first LED emitters, the second LED emitter is one of a plurality of second LED emitters, and the plurality of first LED emitters and the plurality of second LED emitters are arranged in alternating rows to collectively form an array on the submount. In certain embodiments, the first LED emitter is one of a plurality of first LED emitters, the second LED emitter is one of a plurality of second LED emitters, and the plurality of first LED emitters and the plurality of second LED emitters are arranged in a checkerboard pattern to collectively form an array on the submount. The LED device may further comprise a third LED emitter on the submount, the third LED emitter configured to provide light having a third beam angle that is different from the first beam angle and the second beam angle. In certain embodiments, the third LED emitter is configured to provide light having the first peak wavelength. In certain embodiments, the third LED emitter is configured to provide light having a second peak wavelength that is different than the first peak wavelength.

In another aspect, an LED device comprises: a first printed circuit board; a second printed circuit board; a plurality of first LED emitters on the first printed circuit board, each first LED emitter of the plurality of first LED emitters configured to provide light having a first peak wavelength and a first beam angle; and a plurality of second LED emitters on the second printed circuit board, each second LED emitter of the plurality of second LED emitters configured to provide light having the first peak wavelength and a second beam angle, the first beam angle being narrower than the second beam angle. The LED device may further comprise an LED driver configured to drive the plurality of first LED emitters and the plurality of second LED emitters. In certain embodiments, the LED driver is configured to selectively adjust the plurality of first LED emitters and the plurality of second LED emitters to change between the first beam angle and the second beam angle. In certain embodiments, the LED driver is positioned on the first printed circuit board, and the LED driver is electrically coupled to the second printed circuit board by at least one electrical connection that extends between the first printed circuit board and the second printed circuit board. In certain embodiments, the first beam angle differs from the second beam angle in a range from ten degrees to thirty degrees. In certain embodiments, the first beam angle is up to 120 degrees and the second beam angle is up to 140 degrees. In certain embodiments, a spacing between neighboring second LED emitters of the plurality of second LED emitters is less than a spacing between neighboring first LED emitters of the plurality of first LED emitters.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a top view of an exemplary light-emitting diode (LED) device that is populated with a plurality of LED emitters configured to provide various emission characteristics according to embodiments of the present disclosure.

FIG. 1B is a spatial distribution plot for an embodiment of the LED emitters of FIG. 1A.

FIG. 2 is a cross-sectional view of a portion of an LED device that is similar to the LED device of FIG. 1A for embodiments where the LED emitters embody LED packages and LED chips with vertical structures with wire bonds.

FIG. 3 is a cross-sectional view of a portion of an LED device that is similar to the LED device of FIG. 1A for embodiments where the LED emitters embody LED packages and the LED emitters embody LED chips with flip-chip structures.

FIG. 4 is a cross-sectional view of a portion of an LED device that is similar to the LED device of FIG. 1A for embodiments where the LED emitters embody LED packages, the LED emitters embody LED chips, and a lumiphoric material is formed on the LED chips.

FIG. 5 is a cross-sectional view of a portion of an LED device that is similar to the LED device of FIG. 1A for embodiments where both LED emitters embody LED packages.

FIG. 6 is a top view of an LED device that is similar to the LED device of FIG. 1A with an alternative layout of LED emitters.

FIG. 7 is a top view of an LED device that is similar to the LED device of FIG. 6 and the LED device of FIG. 1A for embodiments that include additional LED emitters.

FIG. 8 is a top view of an LED device that is similar to the LED device of FIG. 1A for embodiments that include multiple submounts for a modular structure.

FIG. 9A is an illustration of a horticulture environment where an LED device is positioned to illuminate crops at a first height.

FIG. 9B is an illustration of another horticulture environment where the same LED device of FIG. 9A may be positioned to illuminate the crops at an increased second height and with an adjusted beam angle.

FIG. 10A is an illustration of a horticulture environment similar to the horticulture environment of FIG. 9A for embodiments where multiple LED devices are positioned in an array to illuminate crops.

FIG. 10B is an illustration of another horticulture environment where the same LED devices of FIG. 10A may be positioned to illuminate the crops at an increased second height and with an adjusted beam angle.

FIG. 11A is an illustration of a horticulture environment similar to the horticulture environment of FIG. 9A for embodiments where the LED device dynamically adjusts the beam angle accordingly to crop growth.

FIG. 11B is an illustration of the same horticulture environment of FIG. 11A with a modified beam angle according to crop growth.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to light-emitting diode (LED) devices, and more particularly to mixed packaging arrangements in LED devices. LED structures include different types of LED emitters, including LED packages and bare LED chips, assembled in a common LED device. Bare LED chips are mounted to underlying submounts, such as printed circuit boards, without intervening package elements, such as package submounts and/or lead frame structures. Exemplary LED devices include mixed arrangements of LED emitters configured to selectively provide various emission characteristics such as beam angles and/or wavelengths of light. Exemplary applications include horticulture lighting devices where beam angles and/or peak wavelength may be selectively adjusted by independently controlling various LED emitters of the mixed arrangements.

Before delving into specific details for aspects of the present disclosure, an overview of various elements that may be included in exemplary LED devices is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure may comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements. The active layer may comprise a single quantum well, a multiple quantum well, a double heterostructure, and/or super lattice structures.

The active LED structure may be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). Other material systems include organic semiconductor materials, and other Group III-V systems such as gallium phosphide (GaP), gallium arsenide (GaAs), and related compounds such as aluminum gallium indium phosphide (AlGaInP). The active LED structure may be grown on a growth substrate that can include many materials, such as sapphire, silicon carbide (SiC), silicon, aluminum nitride (AlN), and GaN.

Different embodiments of the active LED structure may emit different wavelengths of light depending on the composition of the active layer. In some embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 700 nm. In certain embodiments, the active LED structure may be configured to emit light that is outside the visible spectrum, including one or more portions of the ultraviolet (UV) spectrum (e.g., 100 nm to 400 nm), or one or more portions of the near infrared spectrum, and/or the infrared spectrum (e.g., 700 nm to 1000 nm).

In the context of horticultural applications, primary chlorophyll absorption peaks exist in certain blue and red ranges, such as a range from 450 nm to 500 nm and in another range from 630 nm to 780 nm. In certain embodiments, LED devices according to the present disclosure are well suited for use as so-called photored devices that target specific red wavelength ranges in various horticultural applications. For example, the specific red wavelength ranges may include a peak wavelength in a range of 630 nm to 780 nm, or a range from 658 nm to 665 nm. Exemplary LED devices may include mixed arrangements of LED emitters of a same peak wavelength range, but with different emission profiles and/or beam angles. In still further embodiments, LED devices according to the present disclosure include mixed arrangements of LED emitters, including combinations of bare LED chips and LED packages, configured to provide a variety of targeted wavelengths for various chlorophyll absorption peaks.

An LED chip can also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphor receiving at least a portion of the light generated by the LED source may re-emit light having a different peak wavelength than the LED source. An LED source and one or more lumiphoric materials may be selected such that their combined output results in light with one or more desired characteristics such as color, color point, intensity, etc.

Lumiphoric materials as described herein may be or include one or more of a phosphor, a scintillator, a lumiphoric ink, a quantum dot material, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. One or more lumiphoric materials may be provided on one or more portions of an LED chip in various configurations. In certain embodiments, lumiphoric materials may be provided over one or more surfaces of LED chips, while other surfaces of such LED chips may be devoid of lumiphoric material.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected.

The present disclosure can be useful for LED chips having a variety of geometries, such as vertical geometry or lateral geometry. A vertical geometry LED chip typically includes anode and cathode connections on opposing sides or faces of the LED chip. A lateral geometry LED chip typically includes both anode and cathode connections on the same side of the LED chip that is opposite a substrate, such as a growth substrate. In certain embodiments, a lateral geometry LED chip may be mounted on a submount of an LED package such that the anode and cathode connections are on a face of the LED chip that is opposite the submount. In this configuration, wire bonds may be used to provide electrical connections with the anode and cathode connections. In other embodiments, a lateral geometry LED chip may be flip-chip mounted on a surface of a submount of an LED package such that the anode and cathode connections are on a face of the active LED structure that is adjacent to the submount. In this configuration, electrical traces or patterns may be provided on the submount for providing electrical connections to the anode and cathode connections of the LED chip. In a flip-chip configuration, the active LED structure is configured between the substrate of the LED chip and the submount for the LED package. Accordingly, light emitted from the active LED structure may pass through the substrate in a desired emission direction. In other embodiments, an active LED structure may be bonded to a carrier submount, and the growth substrate may be removed such that light may exit the active LED structure without passing through the growth substrate.

According to aspects of the present disclosure, LED packages may include one or more elements, such as lumiphoric materials, encapsulants, light-altering materials, lenses, and electrical contacts, among others that are provided with one or more LED chips. In certain aspects, an LED package may include a support structure or support element, such as a submount or a lead frame structure.

Submount structures typically include submounts with electrically conductive traces. Exemplary submount materials include ceramic materials such as aluminum oxide or alumina, AlN, or organic insulators like polyimide (PI) and polyphthalamide (PPA). In certain embodiments, submounts may comprise a printed circuit board (PCB), sapphire, Si or any other suitable material. For PCB embodiments, different PCB types can be used such as standard FR-4 PCB, metal core PCB, or any other type of PCB. Aspects of the present disclosure are also well suited for embodiments with flexible substrates. By way of example, a flexible submount may comprise a polyimide, a polyethylene terephthalate (PET), and the like with electrically conductive traces. Flexible submounts allow improved bonding in a conformal manner to other surfaces that may not be entirely planar.

Lead frame structures typically include electrically conductive leads that are at least partially encased by a body or housing. A lead frame structure may typically be formed of a metal, such as copper, copper alloys, or other conductive metals. The lead frame structure may initially be part of a larger metal structure that is singulated during manufacturing of individual LED packages. Within an individual LED package, isolated portions of the lead frame structure may form anode and cathode connections for an LED chip. The body or housing may be formed of an insulating material that is arranged to surround or encase portions of the lead frame structure. For example, the body or housing may comprise one or more of PPA, PCT, EMC, FR4, BT, impregnated fiber, and/or plastics, etc. The body may be formed on the lead frame structure before singulation so that the individual lead frame portions may be electrically isolated from one another and mechanically supported by the body within an individual LED package. The body may form a cup or a recess in which one or more LED chips may be mounted to the lead frame at a floor of the recess. Portions of the lead frame structure may extend from the recess and through the body to protrude or be accessible outside of the body to provide external electrical connections. An encapsulant material, such as silicone or epoxy, may fill the recess to encapsulate the one or more LED chips.

Encapsulant materials, such as silicone, epoxy, or polymethyl methacrylate (PMMA), among others, may be formed to encapsulate the LED chips over a submount or a lead frame structure. In certain embodiments, one or more lumiphoric materials, such as phosphor particles, may be integrated or otherwise embedded within the encapsulant material. Moreover, encapsulant materials may be shaped to form single lens structures and/or multiple lens structures in a single LED package.

Light-altering materials may be arranged within LED packages, such as along submount surfaces, to reflect or otherwise redirect light from the one or more LED chips in a desired emission direction or pattern. As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, scatter, or otherwise redirect light. For light-reflective materials, the light-altering material may include at least one of fused silica, fumed silica, titanium dioxide (TiO₂), or metal particles suspended in a binder, such as silicone or epoxy. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque color, such as black or gray for absorbing light and increasing contrast. In certain embodiments, the light-altering material includes both light-reflective material and light-absorbing material suspended in a binder.

Challenges exist in efficiently operating LED devices in various environments. LED lighting devices for horticulture applications are selected so that LED devices with specific peak wavelengths are matched to specific primary chlorophyll absorption peaks of targeted crops. In horticulture environments where multiple lighting devices are positioned to provide lighting over a large area, overlapping emission spectrums from neighboring light fixtures can provide regions of higher light intensity. Portions of crops that may receive such higher light intensity may exhibit so-called plant tip bleaching due to overexposure. Challenges exist in maintaining uniform lighting profiles with reduced overlapping emission spectrums of lighting devices. It can be especially challenging considering distances between lighting devices and recipient crops can vary based on different horticulture environments.

LED devices according to the present disclosure include mixed arrangements of LED emitters with various emission characteristics, such as emission profiles or beam angles. Mixed arrangements of LED emitters include combinations of LED packages with different emission characteristics, combinations of bare LED chips and LED packages with different emission characteristics. Exemplary LED devices may be configured to provide a variety of selectable and/or adjustable emission profiles to reduce the effects of overlapping emission spectrums for a variety of horticulture environments. This allows the same LED device to be adjustable for a variety of environments where distances between the LED device and the recipient crop are different. In further embodiments, mixed arrangements of LED emitters include different wavelengths in combination with other variable emission characteristics, such as emission profiles. Such mixed arrangement of LED emitters provides the ability to selectively change peak wavelengths alone or in combination with emission profiles in a horticulture environment to target different crops and/or provide different wavelengths of light during different stages of crop growth. The mixed arrangement of LED emitters in a common LED device provides further improvements in emission patterns, thermal management, and color mixing, among other improvements. Moreover, unpackaged or bare LED chips in the mixed arrangements may permit secondary optics, such as those in lighting fixtures, to be placed closer to these LED chips. Without having to clear dimensions of a package submount and corresponding package bonding materials, secondary optics may be provided with smaller form factors, thereby occupying reduced space with reduced material usage.

As used herein, the beam angle for an LED emitter may be defined in the context of a spatial distribution curve of intensity versus angle normal to the LED emitter. Specifically, the beam angle may be defined as the total angle where the intensity is 50% of the intensity normal to the LED. By way of example, a 120° beam angle would mean the light intensity is 50% of the intensity normal to the emission surface of the LED at angles ±60° from a direction normal to an emission surface of the LED emitter. Beam angle may also be referred to as full width half maximum (FWHM).

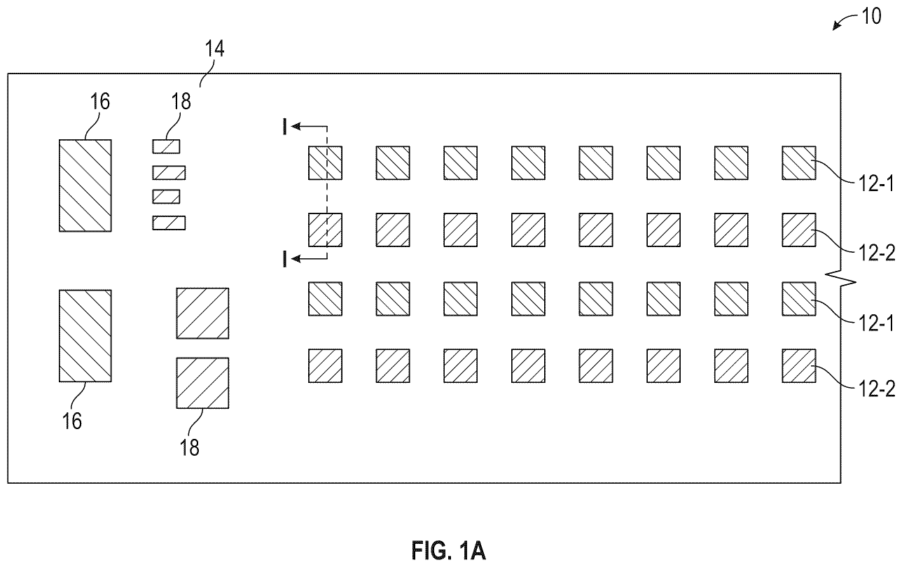

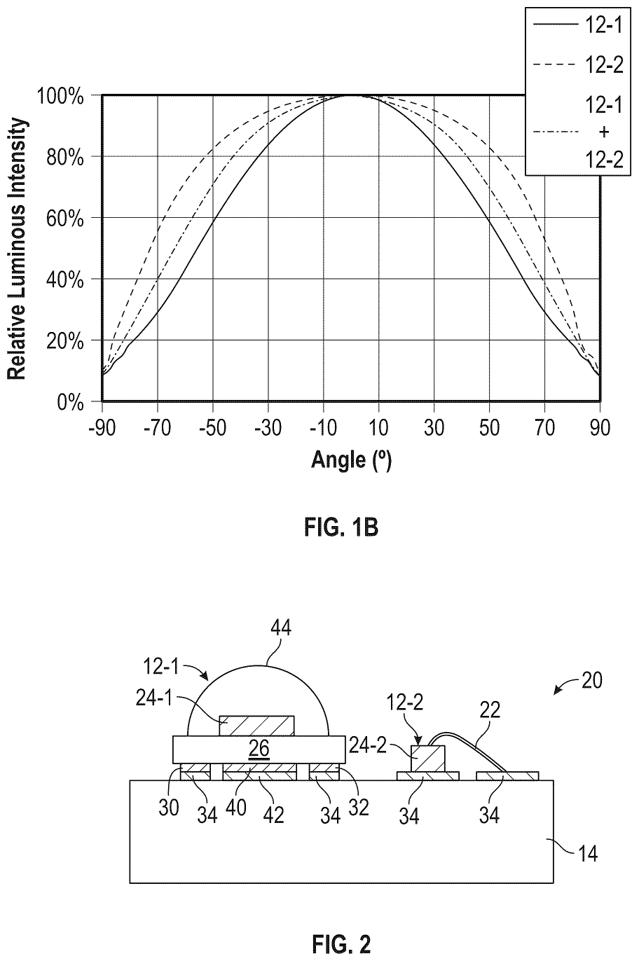

FIG. 1A is a top view of an exemplary LED device 10 that is populated with a plurality of LED emitters 12-1, 12-2 configured to provide various emission characteristics according to embodiments of the present disclosure. By way of example, the LED emitters 12-1 may embody LED packages configured to provide a first beam angle, and the LED emitters 12-2 may embody LED packages configured to provide a second beam angle that is different than the first beam angle. The second beam angle may be wider than the first beam angle. In certain embodiments, both LED emitters 12-1, 12-2 may be configured to emit a same peak wavelength, such as a peak wavelength in a range from 630 nm to 780 nm, or in a range from 658 nm to 665 nm, for various photored applications. In other embodiments, the peak wavelength for the LED emitters 12-1, 12-2 may be in any of the other wavelength ranges listed above. The different emission spectrums may include different beam angles.

As illustrated, the LED emitters 12-1, 12-2 may collectively form an array on a surface of a common submount 14. In certain arrangements, LED emitters 12-1, 12-2 of each type may be arranged together in rows as illustrated by FIG. 1A. By way of example, the submount 14 may embody a printed circuit board with electrically conductive traces connected to the LED emitters 12-1, 12-2. One or more electrical connectors 16 may also be arranged on the submount 14 for receiving external electrical connections. Additionally, one or more other semiconductor devices 18, such as circuit elements that form an LED driver and/or LED controller, may be arranged on the submount 14. The LED driver formed by the semiconductor devices 18 may be electrically connected to the electrical connectors 16 and the LED emitters 12-1, 12-2. In certain embodiments, each type of the LED emitters 12-1, 12-2 may be electrically coupled as a separate string that is electrically coupled to the LED driver so that an output of the LED driver provides individual control for a variety of target beam angles.

In certain embodiments, the LED device 10 may represent a lighting board that resides in a lighting fixture, such as one for horticulture applications. By having the ability to tune emission characteristics for a variety of beam angles, the LED device 10 may be suitable for a variety of environments and/or distances to recipient crops. For applications where a narrower beam angle is desired, the LED driver may adjust the ratio of light provided by the LED emitters 12-1 relative to the LED emitters 12-2, including completely turning off the LED emitters 12-2. In other applications where a wider beam angle is desired, the LED driver may increase amounts of light provided by the LED emitters 12-2 relative to the LED emitters 12-1, including completely turning off the LED emitters 12-1. In both instances, the LED emitters 12-1, 12-2 may be configured to provide a same peak wavelength but with different beam angles. This permits the LED device 10 to be suitable for the same wavelength requirements for a variety of mounting distances to crops. Moreover, the LED device 10 may be adjustable when mounted in a particular environment to provide increased coverage with reduced effects of emission overlap with other LED devices. While two types of LED emitters 12-1, 12-2 are illustrated, the principles described are scalable to additional LED emitters with further variances to emission characteristics, including additional variances to beam angles and/or wavelengths.

FIG. 1B is a spatial distribution plot for an embodiment of the LED emitters 12-1, 12-2 of FIG. 1. The x-axis represents angle in degrees with an angle of 0° representing a beam direction that is normal or perpendicular to the primary light-emitting surface of the LED emitters 12-1, 12-2. The y-axis represents relative luminous intensity. As described above, beam angles for the LED emitters 12-1, 12-2 may be defined as the total angle where the relative luminous intensity is at 50% of the intensity normal to the LED. In the example of FIG. 1B, the LED emitter 12-1 may have a beam angle up to about 140° where the light intensity is 50% for angles of ±70° from 0°, and the LED emitter 12-1 may have a beam angle up to about 110°. In other embodiments, the beam angles for the LED emitters 12-1, 12-2 may have different values, such as differing by at least 10°, or by at least 25°, or by at least 30°, or in a range from 10° to 30°. In another specific example, the LED emitter 12-1 may have a beam angle up to 130° or 140°, and the LED emitter 12-2 may have a beam angle up to 120°. As mentioned above with respect to FIG. 1A, the LED driver may adjust the ratio of light provided by the LED emitters 12-1 relative to the LED emitters 12-2 to dynamically adjust the beam angle of aggregate emissions. By way of example, the spatial distribution plot of FIG. 1B further includes a combined emission example, labeled 12-1+12-2, that represents 50% power concurrently to each of the LED emitters 12-1, 12-2. As illustrated, this provides an aggregate beam angle in between the LED emitter 12-1 and the LED emitter 12-2. With adjustment of the ratio of power to each of the LED emitters 12-1, 12-2, the aggregate beam angle may be dynamically adjusted.

While FIG. 1B is provided for an example with a certain variation in beam angles, different beam angles for the LED emitters 12-1, 12-2 may be provided by various mixed arrangements. For example, the LED emitters 12-1 may embody LED packages with lenses and the LED emitters 12-2 may embody bare LED chips. Bare LED chips may embody vertical structures, lateral structures, or flip-chip structures, and may be configured to provide generally Lambertian emission profiles. In other examples, the LED emitters 12-1, 12-2 may both embody LED packages, but with different lens shapes, such as hemispherical, flat, oval, bullet or complex shapes such as saddle shape configured to produce batwing emission profiles. In certain embodiments, beam angles for either of the LED emitters 12-1, 12-2 may configured with different values, such as 30°, with certain lens shapes, such as a bullet shape among others. In certain embodiments, beam angles for the LED emitters 12-1, 12-2 may be configured with different values that are both in a range from 30° to 140°. FIGS. 2 to 5 are provided to illustrate various examples for the LED emitters 12-1, 12-2. In each figure, the view provided is a cross-sectional view taken along the sectional line I-I of FIG. 1A for the particular embodiment.

FIG. 2 is a cross-sectional view of a portion of an LED device 20 that is similar to the LED device 10 of FIG. 1 for embodiments where the LED emitters 12-1 embody LED packages and the LED emitters 12-2 embody LED chips with vertical structures with wire bonds 22. Each of the LED emitters 12-1, 12-2 include corresponding LED chips 24-1, 24-2. As LED packages, the LED emitter 12-1 includes a package submount 26 and package bonding pads 30, 32. The package bonding pads 30, 32 form anode and cathode connections that are mounted and electrically coupled to corresponding electrically conductive traces 34 of the submount 14. In certain embodiments, the LED emitter 12-1 may include a thermal pad 40 that is mounted and thermally connected to a corresponding electrically conductive trace 42 of the submount 14. The LED emitter 12-1 may further include a lens 44 configured to direct light in targeted emission patterns, such as a curved lens and/or a hemispherical lens.

The LED emitter 12-2 may comprise the LED chip 24-2 in the form of a bare chip or die that is directly mounted to the submount 14 without intervening packaging elements, such as lead frames with housings or submounts of LED packages. When the LED chip 24-2 has a vertical structure, the LED chip 24-2 may be mounted and electrically coupled to one trace 34 and electrically coupled to the other corresponding trace 34 by way of the wire bond 22. With a direct connection to the submount 14, additional thermal interfaces attributed to the submount or lead frame structures of other LED packages are avoided, thereby improving heat dissipation for the LED emitter 12-2 while also reducing associated costs. In certain instances, the active LED structure of the LED chip 24-2 may be formed with a material structure that provides red wavelengths of light that are known to exhibit increased thermal droop compared with blue-emitting LED chips. With increased thermal dissipation to the submount 14, the LED emitter 12-2 may be operated with increased efficiency. In certain embodiments, the LED emitters 12-1 may form LED packages that also provide red wavelengths. Accordingly, some red light from the LED emitter 12-1 may be shaped by the corresponding lens 44 and other red light from the LED emitter 12-2 may provide an emission profile based on the LED chip 24-2 itself. The ability to mix emission profiles from lensed LED chips (e.g., 24-1) and un-lensed LED chips (e.g., 24-2) advantageously allows dynamic shaping of emission patterns by changing current flow through different strings of the LED emitters 12-1, 12-2.

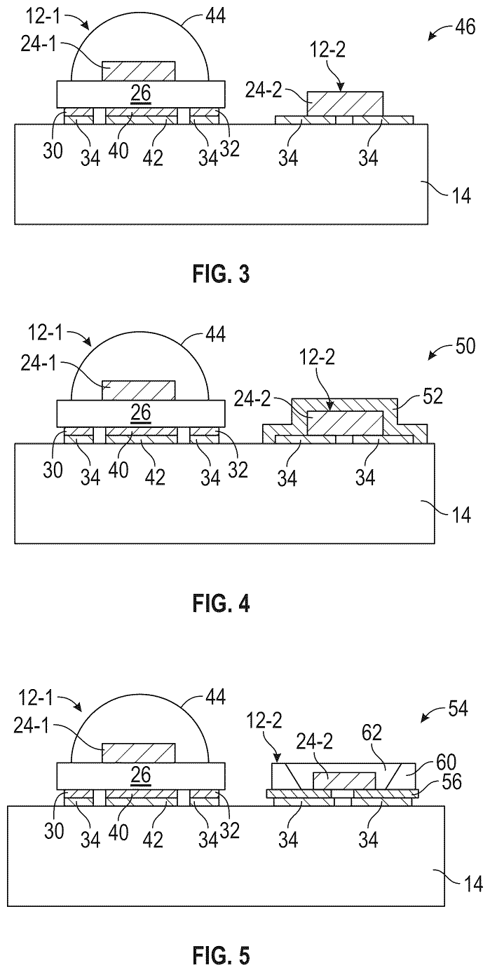

FIG. 3 is a cross-sectional view of a portion of an LED device 46 that is similar to the LED device 10 of FIG. 1A for embodiments where the LED emitters 12-1 embody LED packages and the LED emitters 12-2 embody LED chips with flip-chip structures. Such an arrangement avoids positioning wire bonds in the primary light emission direction for the LED emitter 12-2. Moreover, a flip-chip structure for the LED chip 24-2 may generate a different emission pattern than the vertical structure of FIG. 2 for different applications.

FIG. 4 is a cross-sectional view of a portion of an LED device 50 that is similar to the LED device 10 of FIG. 1A for embodiments where the LED emitters 12-1 embody LED packages, the LED emitters 12-2 embody LED chips, and a lumiphoric material 52 is formed on the LED chips. As illustrated, the lumiphoric material 52 may be deposited or otherwise formed on a top surface and sidewalls of the LED chip 24-2 and on surfaces of the submount 14 adjacent the LED chip 24-2. The lumiphoric material 52 may comprise a phosphor configured to convert at least a portion of light from the LED chip 24-2 to a different wavelength.

FIG. 5 is a cross-sectional view of a portion of an LED device 54 that is similar to the LED device 10 of FIG. 1A for embodiments where both LED emitters 12-1, 12-2 embody LED packages. In the example of FIG. 5, the LED emitter 12-1 is configured the same as described above with respect to FIG. 2. The LED emitter 12-2 may comprise lead frames 56 with corresponding housings 60. A portion of the housing 60 may form a recess that is filled with an encapsulant 62. The encapsulant 62 may comprise silicone or epoxy and may form a generally flat upper surface in certain embodiments. The encapsulant 62 may be light transparent to light from the LED chip 24-2. In certain embodiments, the encapsulant may include a lumiphoric material, such as phosphor particles intermixed in a binder material of silicone or epoxy. Aggregate emissions from the LED emitter 12-2 may include wavelengths generated by the LED chip 24-2 and wavelengths generated by wavelength conversion from the lumiphoric material. The different structures for the lens 44 of the LED emitter 12-1 relative to the encapsulant 62 of the LED emitter 12-2 may provide different beam angles, even for embodiments where the LED chips 24-1, 24-2 emit the same peak wavelength.

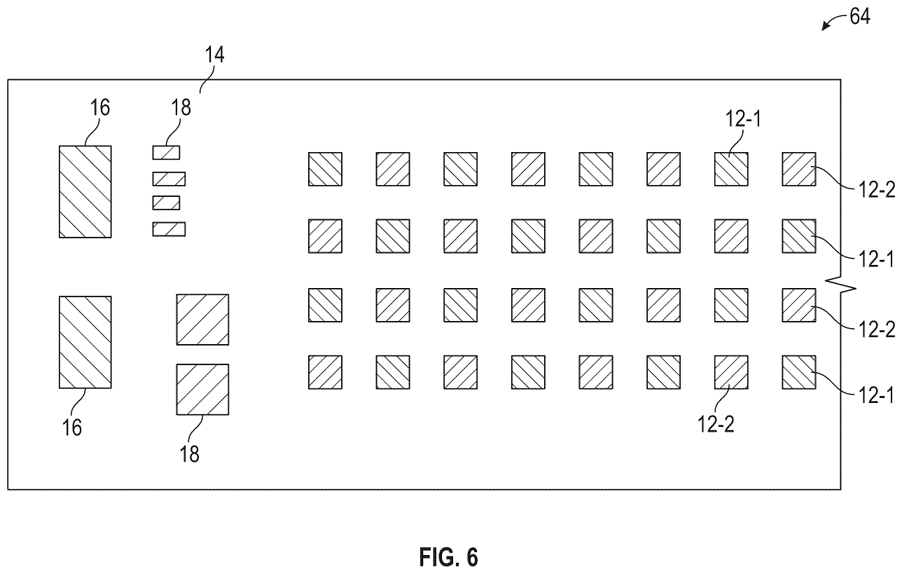

FIG. 6 is a top view of an LED device 64 that is similar to the LED device 10 of FIG. 1A with an alternative layout of LED emitters 12-1, 12-2. Instead of being arranged in separate rows, the LED emitters 12-1, 12-2 are further mixed within the larger array. For example, the LED emitters 12-1, 12-2 may alternate with one another along one or more rows and/or columns of the array in a checkerboard pattern. By arranging the LED emitters 12-1, 12-2 in with additional mixing within the array, the overall emission appearance of the LED device 64 may appear relatively uniform when toggling between the LED emitters 12-1 and the LED emitters 12-2.

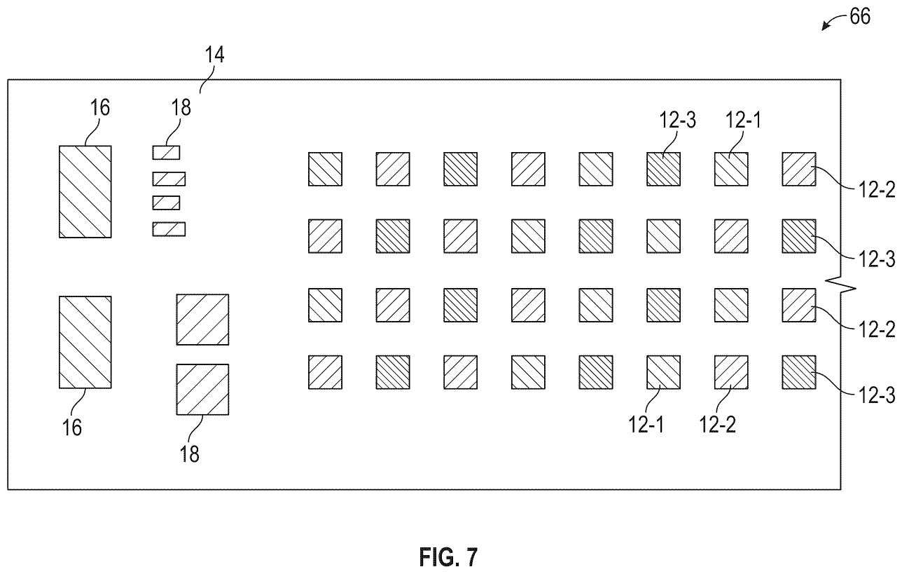

FIG. 7 is a top view of an LED device 66 that is similar to the LED device 64 of FIG. 6 and the LED device 10 of FIG. 1A for embodiments that include additional LED emitters 12-3. The LED emitters 12-3 may be configured to provide a different emission characteristic than both the LED emitters 12-1 and 12-2. For example, the LED emitters 12-3 may be configured to provide a third beam angle that is different than a first beam angle of the LED emitters 12-1 and different than a second beam angle of the LED emitters 12-2. Accordingly, the LED device 66 may be configured to provide at least three different beam angles for aggregate emissions. Moreover, the LED device 66 may be configured to be tunable between each of the beam angles by selectively adjusting a ratio of current to each of the LED emitters 12-1 to 12-3. In other embodiments, the LED emitters 12-3 may provide a different peak wavelength than the LED emitters 12-1 and 12-2. For example, the LED emitters 12-3 may be configured to provide ambient lighting while the specific peak wavelengths of the other LED emitters 12-1, 12-2 may provide targeted chlorophyll absorption peaks.

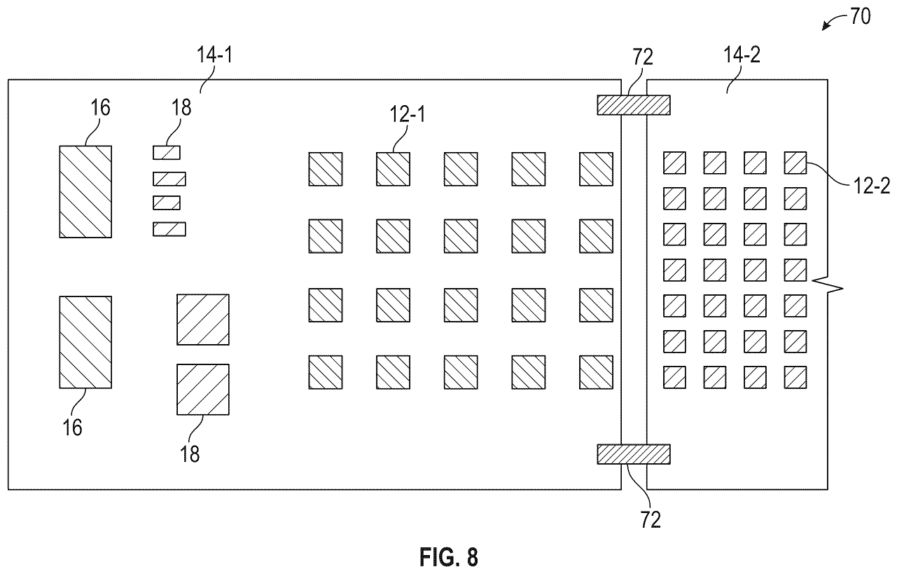

FIG. 8 is a top view of an LED device 70 that is similar to the LED device 10 of FIG. 1A for embodiments that include multiple submounts 14-1, 14-2 for a modular structure. In certain embodiments, a first submount 14-1 may be electrically coupled to a second submount 14-2 by way of one or more electrical connections 72, such as jumpers, that extend between the two submounts 14-1, 14-2. In certain embodiments, the LED emitters 12-1 may form an array on the first submount 14-1 and the LED emitters 12-2 may form an array on the second submount. The semiconductor device 18 of the first submount 14-1 may form circuit elements such as LED drivers and/or LED controllers that control both the LED emitters 12-1 and the LED emitters 12-2. In certain embodiments, the LED emitters 12-1 embody LED packages and the LED emitters 12-2 embody bare LED chips. Accordingly, the LED emitters 12-2 may be arranged in an array with increased packing density where a pitch between neighboring LED emitters 12-2 is reduced compared with the LED emitters 12-1.

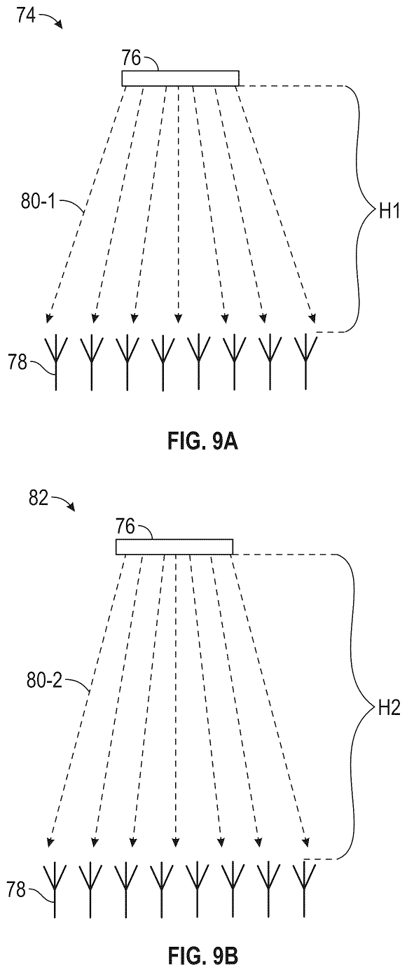

As described above, LED devices according to the present disclosure are well suited for use in applications where variable emission characteristics are desired. In one example, a same LED device is configured with an adjustable beam angle to permit use at a variety of heights from an illumination surface. If the distance to the illumination surface is changed, the beam angle of the LED device may be adjusted by controlling current to certain LED emitters to correlate the emission pattern to a target area. In another example, multiple LED devices may be assembled together in a common room or space, and the beam angles of each LED device may be dynamically adjusted to reduce and/or avoid overlapping emission areas. Exemplary applications include horticulture lighting as well as general illumination in various business environments, such as illumination of product in retail stores or illumination of bar tops and/or table tops at differing heights or task planes in restaurants. Additional applications include outdoor illumination, such as building lighting, roadway lighting, street lighting, pedestrian pathway lighting, marine lighting, and lighting along coastlines configured to avoid disruption of wildlife, such as sea turtle nesting and/or hatching behavior. In certain embodiments, outdoor illumination devices with variable emission characteristics may be implemented in areas where light levels are dynamically adjusted according to activity periods, such as increased emissions and/or beam angles during peak automobile or pedestrian traffic and reduced emissions and/or beam angles after peak traffic periods. For indoor and outdoor illumination devices, variable emission characteristics may include providing a first aggregate emission color, such as a generally white light during business hours for enhanced color rendering, followed by a second aggregate emission color, such as a lower color temperature white light or even amber light after business hours. FIGS. 9A to 11B are provided in the context of horticulture applications; however, the principles described are applicable to any of the lighting applications described above.

FIG. 9A is an illustration of a horticulture environment 74 where an LED device 76 is positioned to illuminate crops 78. The LED device 76 may embody any of the LED devices described above with respect to FIGS. 1A to 8. A first distance between the LED device 76 and the crops 78 may be defined by a first height H1. A first beam angle 80-1 for the LED device 76 is represented by the dashed line arrows extending from the LED device 76 toward the crops 78. To ensure suitable illumination for chlorophyll absorption, the first beam angle 80-1 should be wide enough to encompass the crops 78.

FIG. 9B is an illustration of another horticulture environment 82 where the LED device 76 of FIG. 9A is positioned to illuminate the crops 78 with an increased distance compared with the horticulture environment 74 of FIG. 9A. The increased distance may be due to a different ceiling height and/or a different mounting position for the LED device 76. In FIG. 9B, a second distance between the LED device 76 and the crops 78 may be defined by a second height H2. In view of the increased second height H2, the LED device 76 may be adjusted to a second beam angle 80-2 that ensures suitable coverage of the crops 78 with reduced excess illumination lost outside of an area of the crops 78. As described above, the LED device 76 may be configured to provide a same peak wavelength or combination of peak wavelengths while also being capable of providing a selectable beam angle.

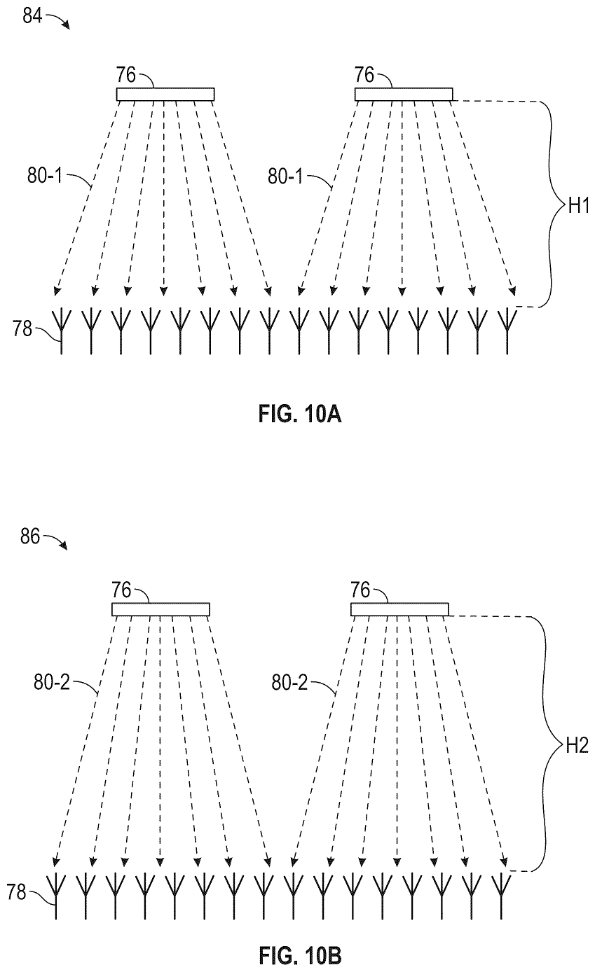

FIG. 10A is an illustration of a horticulture environment 84 similar to the horticulture environment 74 of FIG. 9A for embodiments where multiple LED devices 76 are positioned in an array to illuminate crops 78. For a larger target illumination area of crops 78, multiple ones of the LED device 76 may be arranged together to provide aggregate emissions for suitable coverage and chlorophyll absorption. As illustrated, the first beam angle 80-1 for each LED device 76 is adjusted to reduce and/or avoid emission overlap at the crops 78. If the first beam angles 80-1 overlapped, the particular areas of crops 78 may be subject to plant tip bleaching due to over illumination.

FIG. 10B is an illustration of another horticulture environment 86 where the LED devices 76 of FIG. 10A are positioned to illuminate the crops 78 with an increased distance compared with the horticulture environment 84 of FIG. 10A. As described above with respect to FIGS. 9A and 9B, the increased distance in FIG. 10B may be represented by the second height H2 which is greater than the first height H1 of FIG. 10A. At the increased height H2, the LED devices 76 are adjusted to the second beam angle 80-2 to reduce and/or avoid emission overlap at the crops 78.

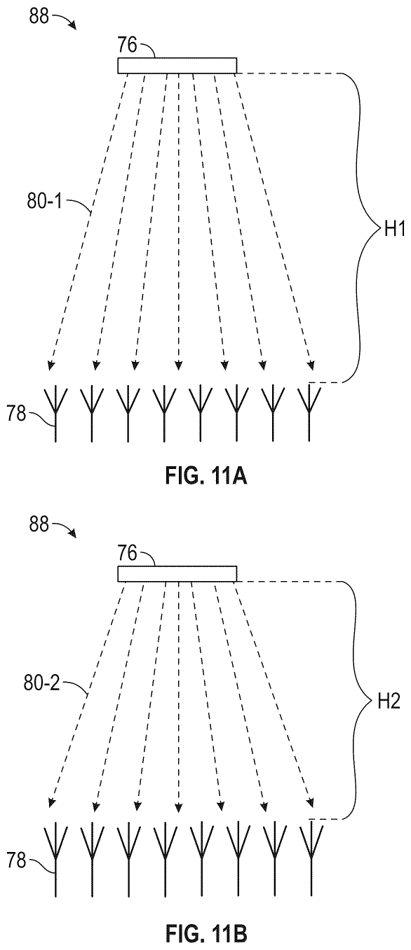

FIGS. 11A and 11B illustrate the example of a horticulture environment 88 similar to the horticulture environment 74 of FIG. 9B for embodiments where the LED device 76 is dynamically adjusted according to growth of the crops 78. As illustrated in FIG. 11A, the LED device 76 is configured to provide the first beam angle 80-1 based on the first height H1 to the crops 78. As the crops grow taller, the first beam angle 80-1 may not be sufficient to provide light to the entire canopy of the crops 78, particularly along perimeter edges of the canopy. As illustrated by FIG. 11B, the LED device 76 may dynamically adjust operation to provide the second beam angle 80-2 based on the second height H2 of the crops 78 after some growth has occurred. In order to provide illumination to cover the canopy of the crops 78 at the second height H2, which is less than the first height H1, the LED device 76 may dynamically adjust to the second beam angle 80-2. In certain embodiments, the beam angle 80-2 may be continuously adjusted in an automatic fashion during a growth cycle for the crops 78. By way of example, if the second height H2 represents the crops 78 at the end of their growth cycle, the LED device 76 may continuously adjust from the first beam 80-1 to the second beam angle 80-2 during the growth cycle.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) device comprising:
a submount comprising a printed circuit board;
a first LED emitter on the submount, the first LED emitter configured to provide light having a first peak wavelength and a first beam angle; and
a second LED emitter on the submount, the second LED emitter configured to provide light having the first peak wavelength and a second beam angle, the first beam angle being narrower than the second beam angle.

2. The LED device of claim 1, further comprising:
an LED driver on the submount, the LED driver configured to electrically activate the first LED emitter and the second LED emitter independently of one another to change between the first beam angle and the second beam angle.

3. The LED device of claim 1, wherein the first beam angle differs from the second beam angle by at least ten degrees.

4. The LED device of claim 3, wherein the first beam angle differs from the second beam angle in a range from ten degrees to thirty degrees.

5. The LED device of claim 3, wherein the first beam angle is up to 120 degrees and the second beam angle is up to 140 degrees.

6. The LED device of claim 1, wherein the first peak wavelength is in a range from 630 nanometers (nm) to 780 nm.

7. The LED device of claim 1, wherein:
the first LED emitter comprises an LED package with a first LED chip mounted to a package submount and a lens over the first LED chip; and
the second LED emitter comprises a second LED chip mounted directly to the submount.

8. The LED device of claim 7, further comprising a lumiphoric material on the second LED emitter and on a portion of the submount adjacent the second LED emitter.

9. The LED device of claim 1, wherein the first LED emitter is one of a plurality of first LED emitters, the second LED emitter is one of a plurality of second LED emitters, and the plurality of first LED emitters and the plurality of second LED emitters are arranged in alternating rows to collectively form an array on the submount.

10. The LED device of claim 1, wherein the first LED emitter is one of a plurality of first LED emitters, the second LED emitter is one of a plurality of second LED emitters, and the plurality of first LED emitters and the plurality of second LED emitters are arranged in a checkerboard pattern to collectively form an array on the submount.

11. The LED device of claim 1, further comprising a third LED emitter on the submount, the third LED emitter configured to provide light having a third beam angle that is different from the first beam angle and the second beam angle.

12. The LED device of claim 11, wherein the third LED emitter is configured to provide light having the first peak wavelength.

13. The LED device of claim 11, wherein the third LED emitter is configured to provide light having a second peak wavelength that is different than the first peak wavelength.

14. A light-emitting diode (LED) device comprising:
a first printed circuit board;
a second printed circuit board;
a plurality of first LED emitters on the first printed circuit board, each first LED emitter of the plurality of first LED emitters configured to provide light having a first peak wavelength and a first beam angle; and
a plurality of second LED emitters on the second printed circuit board, each second LED emitter of the plurality of second LED emitters configured to provide light having the first peak wavelength and a second beam angle, the first beam angle being narrower than the second beam angle.

15. The LED device of claim 14, further comprising an LED driver configured to drive the plurality of first LED emitters and the plurality of second LED emitters.

16. The LED device of claim 15, wherein the LED driver is configured to selectively adjust the plurality of first LED emitters and the plurality of second LED emitters to change between the first beam angle and the second beam angle.

17. The LED device of claim 15, wherein the LED driver is positioned on the first printed circuit board, and the LED driver is electrically coupled to the second printed circuit board by at least one electrical connection that extends between the first printed circuit board and the second printed circuit board.

18. The LED device of claim 14, wherein the first beam angle differs from the second beam angle in a range from ten degrees to thirty degrees.

19. The LED device of claim 18, wherein the first beam angle is up to 120 degrees and the second beam angle is up to 140 degrees.

20. The LED device of claim 14, wherein a spacing between neighboring second LED emitters of the plurality of second LED emitters is less than a spacing between neighboring first LED emitters of the plurality of first LED emitters.
